(19) United States
(12) Patent Application Publication
(10) Pub. No.: US 2026/0344068 A1
(43) Pub. Date: Oct. 29, 2026

(54) STRUCTURES FOR A PHOTODETECTOR THAT INCLUDE AN ADDITIONAL TERMINAL

(71) Applicant: GlobalFoundries U.S. Inc., Malta, NY (US)

(72) Inventors: Ranjan Das, Leuven (BE); Bartlomiej Jan Pawlak, Leuven (BE)

(21) Appl. No.: 19/188,647

(22) Filed: Apr. 24, 2025

(51) Int. Cl. H10F 30/225; G02B 6/30; H10F 71/00; H10F 77/1223; H10F 77/16

(52) U.S. Cl. CPC H10F 30/2255; G02B 6/305; H10F 71/121; H10F 77/1223; H10F 77/16

(57) ABSTRACT

Structures for a photodetector and methods of forming a structure for a photodetector. The structure comprises a photodetector including a pad comprised of a semiconductor material, a conductor layer, a first undoped region in the pad, a second undoped region in the pad, a doped region in the pad, and a semiconductor layer on the first undoped region. The doped region is laterally arranged between the first undoped region and the second undoped region, and the conductor layer overlies the doped region.

### BACKGROUND

This disclosure relates to photonic chips and, more specifically, to structures for a photodetector and methods of forming such structures.

Photonic chips are used in many applications and systems including, but not limited to, data communication systems and data computation systems. A photonic chip includes a photonic integrated circuit comprised of photonic components, such as modulators, polarizers, and couplers, that are used to manipulate light received from a light source, such as an optical fiber or a laser. A photodetector may be employed in the photonic integrated circuit to convert light, which may be modulated as an optical signal, into an electrical signal.

An avalanche photodetector is a type of photodetector belonging to the same photonic component family as photodiodes. When an avalanche photodetector is placed under a high reverse bias, photon-initiated charge carriers are accelerated by the high electric field to a kinetic energy that is large enough to knock electrons out of atoms of the bulk material and generate additional charge carriers that may exponentially grow to generate an avalanche of charge carriers.

An avalanche photodetector lacks any mechanism to provide a dynamic gain and the signal-to-noise ratio of an avalanche photodetector is difficult to optimize. An avalanche photodetector may also suffer from reduced reliability due to the high reverse bias that is applied during operation.

Improved structures for a photodetector and methods of forming such structures are needed.

### SUMMARY

In an embodiment of the invention, a structure for a photonic chip is provided. The structure comprises a photodetector including a pad comprised of a semiconductor material, a conductor layer, a first undoped region in the pad, a second undoped region in the pad, a doped region in the pad, and a semiconductor layer on the first undoped region. The doped region is laterally arranged between the first undoped region and the second undoped region, and the conductor layer overlies the doped region.

In an embodiment of the invention, a method of forming a structure for a photonic chip is provided. The method comprises forming a photodetector including a pad comprised of a semiconductor material, a conductor layer, a first undoped region in the pad, a second undoped region in the pad, a doped region in the pad, and a semiconductor layer on the first undoped region. The doped region is laterally arranged between the first undoped region and the second undoped region, and the conductor layer overlies the doped region.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIG. 1 is a top view of a structure at an initial fabrication stage of a processing method in accordance with embodiments of the invention.

FIG. 1A is a cross-sectional view taken generally along line 1A-1A in FIG. 1.

FIG. 2 is a top view of the structure at a fabrication stage of the processing method subsequent to FIGS. 1, 1A.

FIG. 2A is a cross-sectional view taken generally along line 2A-2A in FIG. 2.

FIG. 3 is a cross-sectional view of the structure at a fabrication stage of the processing method subsequent to FIGS. 2, 2A.

FIG. 4 is a cross-sectional view of a structure in accordance with alternative embodiments of the invention.

FIG. 5 is a cross-sectional view of a structure in accordance with alternative embodiments of the invention.

### DETAILED DESCRIPTION

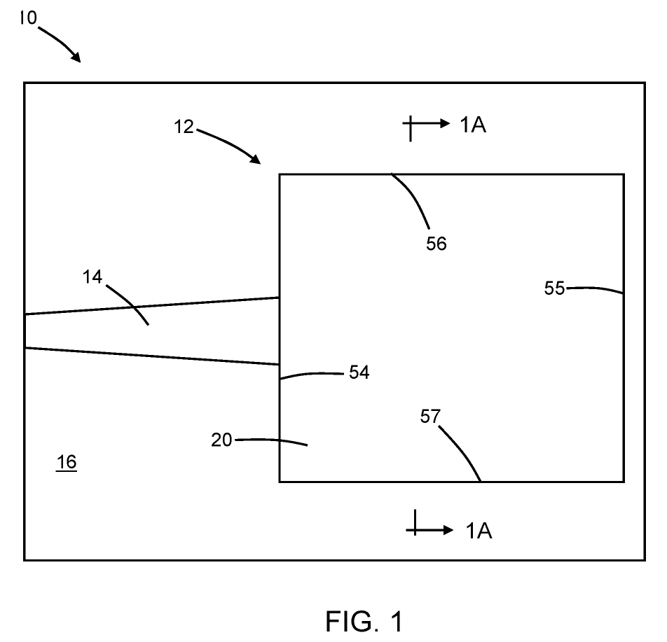

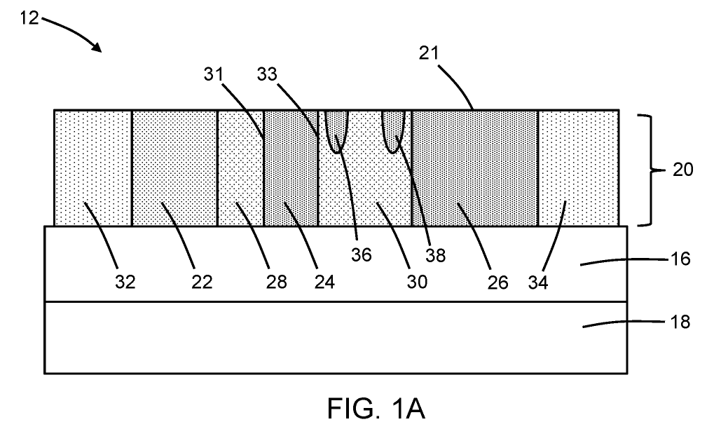

With reference to FIGS. 1, 1A and in accordance with embodiments of the invention, a structure 10 for a photodetector 12 and a waveguide core 14 that is coupled to the photodetector 12. The photodetector 12 and the waveguide core 14 are positioned on, and overlie, a dielectric layer 16 and a semiconductor substrate 18. In an embodiment, the dielectric layer 16 may be comprised of a dielectric material, such as an oxide of silicon (e.g., silicon dioxide), and the underlying semiconductor substrate 18 may be comprised of a semiconductor material, such as single-crystal silicon. In an embodiment, the dielectric layer 16 may be a buried oxide layer of a silicon-on-insulator substrate. The dielectric layer 16 may provide low-index cladding that separates the photodetector 12 and the waveguide core 14 from the semiconductor substrate 18.

The photodetector 12 includes a pad 20 that is positioned on the dielectric layer 16. The pad 20 includes a top surface 21, a side edge 54, a side edge 55 opposite from the side edge 54, a side edge 56, and a side edge 57 opposite from the side edge 56. The side edges 54, 55, 56, 57 surround a perimeter of the pad 20. The waveguide core 14 may include a tapered section that adjoins the side edge 54 of the pad 20. The tapered section of the waveguide core 14 may have a width dimension that increases with decreasing distance from the side edge 54. In an embodiment, the width dimension of the tapered section of the waveguide core 14 may increase linearly with decreasing distance from the side edge 54. In an alternative embodiment, the width dimension of the tapered section of the waveguide core 14 may vary based on a non-linear function, such as a quadratic function, a cubic function, a parabolic function, a sine function, a cosine function, a Bezier function, or an exponential function. In an embodiment, the tapered section of the waveguide core 14 may include a single stage of tapering characterized by a taper angle. In an alternative embodiment, the tapered section of the waveguide core 14 may taper in multiple stages each characterized by a different taper angle.

In an embodiment, the waveguide core 14 and the pad 20 of the photodetector 12 may be comprised of a material having a refractive index that is greater than the refractive index of silicon dioxide. In an embodiment, the waveguide core 14 and the pad 20 of the photodetector 12 may be comprised of a semiconductor material. In an embodiment, the waveguide core 14 and the pad 20 of the photodetector 12 may be comprised of single-crystal silicon. The waveguide core 14 and the pad 20 of the photodetector 12 may be formed by patterning a layer comprised of their constituent material with lithography and etching processes. In an embodiment, the waveguide core 14 and the pad 20 of the photodetector 12 may be formed by patterning the semiconductor material, which may be single-crystal silicon, of the device layer of a silicon-on-insulator substrate.

The pad 20 may include a doped region 22, a doped region 24, a doped region 26, an undoped region 28, an undoped region 30, a doped region 32, and a doped region 34. The doped region 24 and the doped region 26 may have an opposite conductivity type from the doped region 22. The undoped region 28 and the undoped region 30 may be comprised of intrinsic semiconductor material. The doped region 24 adjoins the undoped region 28 along an interface 31, the doped region 24 adjoins the undoped region 30 along an interface 33, and the interfaces 31, 33 may extend in a vertical direction relative to the dielectric layer 16 and the semiconductor substrate 18.

The doped regions 22, 24, 26 and the undoped regions 28, 30 are arranged in a lateral direction between the doped region 32 and the doped region 34. The doped region 22 is arranged in a lateral direction between the undoped region 28 of intrinsic semiconductor material and the doped region 32. The doped region 24 is arranged in a lateral direction between the undoped region 28 of intrinsic semiconductor material and the undoped region 30 of intrinsic semiconductor material. The doped region 26 is arranged in a lateral direction between the undoped region 30 of intrinsic semiconductor material and the doped region 34. The doped region 32 is arranged proximate to the side edge 56 of the pad 20, and the doped region 34 is arranged proximate to the side edge 57 of the pad 20.

The doped region 22 may be formed by, for example, ion implantation with an implantation mask with an opening that determines an implanted area of the pad 20. The implantation mask may include a layer of photoresist applied by a spin-coating process, pre-baked, exposed to light projected through a photomask, baked after exposure, and developed with a chemical developer to define the opening over the area of the pad 20 to be implanted. The implantation conditions, such as ion species, dose, and kinetic energy, may be selected to tune the electrical and physical characteristics of the doped region 22. The implantation mask may be stripped after forming the doped region 22. In an embodiment, the semiconductor material of the doped region 22 may contain an n-type dopant, such as arsenic or phosphorus, that provides n-type electrical conductivity.

The doped regions 24, 26 may be formed by, for example, ion implantation with an implantation mask having openings that determine the implanted areas of the pad 20. The implantation mask may include a layer of photoresist applied by a spin-coating process, pre-baked, exposed to light projected through a photomask, baked after exposure, and developed with a chemical developer to define openings over the areas of the pad 20 to be implanted. The implantation conditions, such as ion species, dose, and kinetic energy, may be selected to tune the electrical and physical characteristics of the doped regions 24, 26. The implantation mask may be stripped after forming the doped regions 24, 26. In an embodiment, the semiconductor material of the doped regions 24, 26 may contain a p-type dopant, such as boron, that provides p-type electrical conductivity.

The doped region 32 may be formed by, for example, ion implantation with an implantation mask with an opening that determines an implanted area of the pad 20. The implantation mask may include a layer of photoresist applied by a spin-coating process, pre-baked, exposed to light projected through a photomask, baked after exposure, and developed with a chemical developer to define the opening over the area of the pad 20 to be implanted. The implantation conditions, such as ion species, dose, and kinetic energy, may be selected to tune the electrical and physical characteristics of the doped region 32. The implantation mask may be stripped after forming the doped region 32. In an embodiment, the semiconductor material of the doped region 32 may contain an n-type dopant, such as arsenic or phosphorus, that provides n-type electrical conductivity. The doped region 32 may be more heavily doped than the adjacent doped region 22.

The doped region 34 may be formed by, for example, ion implantation with an implantation mask with an opening that determines an implanted area of the pad 20. The implantation mask may include a layer of photoresist applied by a spin-coating process, pre-baked, exposed to light projected through a photomask, baked after exposure, and developed with a chemical developer to define the opening over the area of the pad 20 to be implanted. The implantation conditions, such as ion species, dose, and kinetic energy, may be selected to tune the electrical and physical characteristics of the doped region 34. The implantation mask may be stripped after forming the doped region 34. In an embodiment, the semiconductor material of the doped region 34 may contain a p-type dopant, such as boron, that provides p-type electrical conductivity. The doped region 34 may be more heavily doped than the adjacent doped region 26.

In an embodiment, a doped region 36 and a doped region 38 may be formed in the pad 20 within the undoped region 30. The doped regions 36, 38 adjoin the top surface 21, and the doped regions 36, 38 extend from the top surface 21 partially through the undoped region 30. The doped region 36 is laterally arranged adjacent to the doped region 24 and the interface 33. The doped region 38 is laterally arranged adjacent to the doped region 26.

The doped regions 36, 38 may be formed by, for example, ion implantation with an implantation mask having openings that determine the implanted areas of the pad 20. The implantation mask may include a layer of photoresist applied by a spin-coating process, pre-baked, exposed to light projected through a photomask, baked after exposure, and developed with a chemical developer to define openings over the areas of the pad 20 to be implanted. The implantation conditions, such as ion species, dose, and kinetic energy, may be selected to tune the electrical and physical characteristics of the doped regions 36, 38. The implantation mask may be stripped after forming the doped regions 36, 38. In an embodiment, the semiconductor material of the doped regions 36, 38 may contain an n-type dopant, such as phosphorus, that provides n-type electrical conductivity.

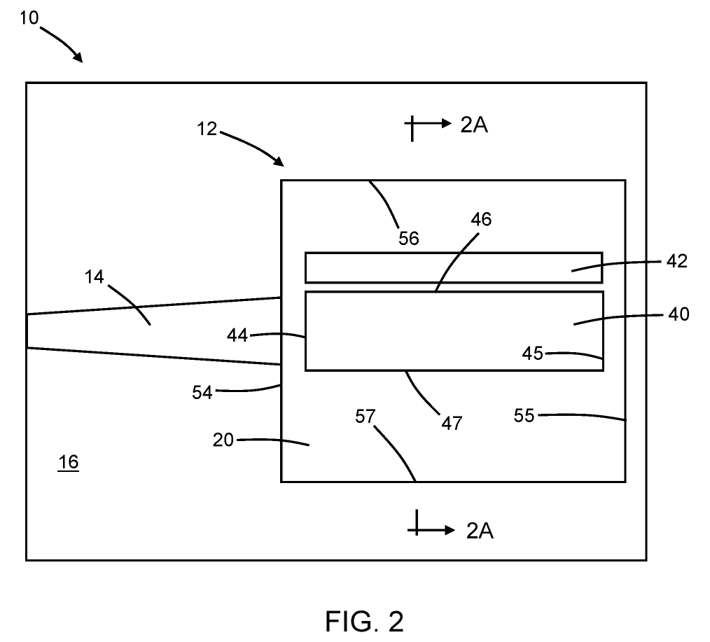

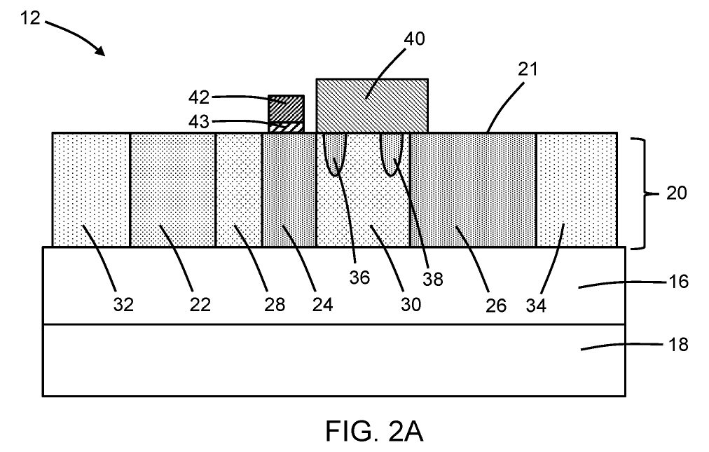

With reference to FIGS. 2, 2A in which like reference numerals refer to like features in FIGS. 1, 1A and at a subsequent fabrication stage, the photodetector 12 further includes a semiconductor layer 40 representing a light-absorbing region that may overlie the top surface 21 of the pad 20 and, more specifically, that may overlie the undoped region 30. The semiconductor layer 40 is arranged on the pad 20 with an inward spacing from the outer perimeter of the pad 20. The semiconductor layer 40 may have a perimeter surrounded by a sidewall 44, a sidewall 45 opposite from the sidewall 44, a sidewall 46, and a sidewall 47 opposite from the sidewall 46. The sidewall 44 is positioned adjacent to the side edge 54 of the pad 20, the sidewall 45 is positioned adjacent to the side edge 55 of the pad 20, the sidewall 46 is positioned adjacent to the side edge 56 of the pad 20, and the sidewall 47 is positioned adjacent to the side edge 57 of the pad 20.

The semiconductor layer 40 of the photodetector 12 may be comprised of a light-absorbing material that is configured to absorb light of a given wavelength, such as a wavelength within an infrared wavelength band of the electromagnetic spectrum, and to generate charge carriers from photons of the absorbed light by photoelectric conversion. In an embodiment, the semiconductor layer 40 may be comprised of a different material from the waveguide core 14 and/or the pad 20. In an embodiment, the semiconductor layer 40 may be comprised of a material having a composition that includes germanium. In an embodiment, the semiconductor layer 40 may be comprised of germanium that is undoped and intrinsic. In an alternative embodiment, the semiconductor layer 40 may be comprised of germanium that is doped with a p-type dopant to provide p-type electrical conductivity.

In an embodiment, the semiconductor layer 40 may be positioned fully above the top surface 21. In an embodiment, the semiconductor layer 40 may be epitaxially grown from the top surface 21 of the pad 20 and then patterned by lithography and etching processes.

The semiconductor layer 40 adjoins the pad 20 over a horizontal interface along a portion of the top surface 21 of the pad 20 and across which the type of semiconductor material changes from the semiconductor material of the pad 20 to the semiconductor material of the semiconductor layer 40. The doped region 36 is positioned adjacent to the sidewall 46 of the semiconductor layer 40, and the doped region 38 is positioned adjacent to the sidewall 47 of the semiconductor layer 40. In an embodiment, the doped region 36 may be laterally offset from the sidewall 46, and the doped region 38 may be laterally offset from the sidewall 47. In an embodiment, the semiconductor layer 40 may fully overlap with the doped regions 36, 38. In an embodiment, the semiconductor layer 40 may partially overlap with the doped regions 36, 38.

A conductor layer 42 and an insulator layer 43 may be formed on a portion of the top surface 21 of the pad 20 that overlies the doped region 24. The insulator layer 43 may be positioned in a vertical direction between the conductor layer 42 and the top surface 21 of the pad 20. In an embodiment, the insulator layer 43 may be positioned fully between the conductor layer 42 and the top surface 21 of the pad 20. In an embodiment, the conductor layer 42 and the insulator layer 43 may overlie a portion of the doped region 24. In an embodiment, the conductor layer 42 and the insulator layer 43 may be positioned adjacent to the sidewall 46 of the semiconductor layer 40 and laterally between the sidewall 46 of the semiconductor layer 40 and the side edge 56 of the pad 20. In an embodiment, the conductor layer 42 may be comprised of a conductor, such as doped polysilicon, and the insulator layer 43 may be comprised of a dielectric material, such as an oxide of silicon (e.g., silicon dioxide).

The insulator layer 43 adjoins the portion of the top surface 21 of the pad 20 that overlies the doped region 24 along an interface oriented in a horizontal direction relative to the plane of the dielectric layer 16 and the plane of the semiconductor substrate 18. The horizontal interface may be oriented transverse to the interface 31 between the doped region 24 and the undoped region 28, as well as oriented transverse to the interface 31 between the doped region 24 and the undoped region 30.

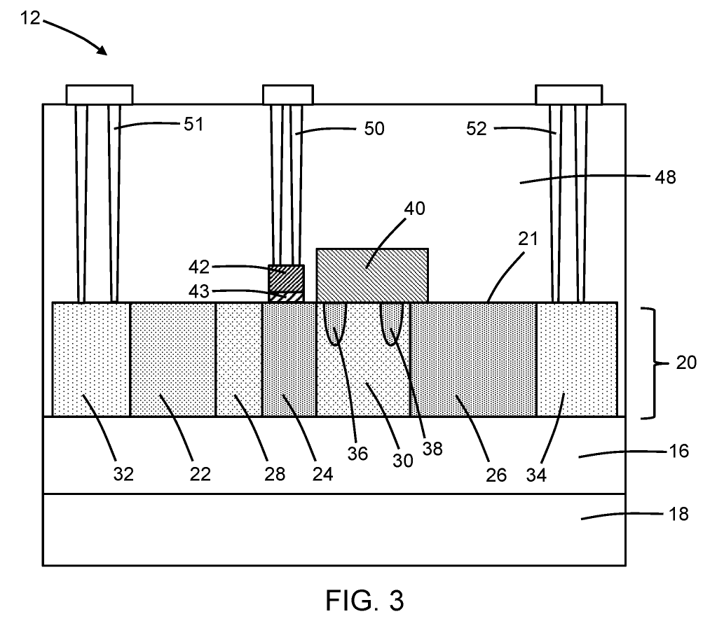

With reference to FIG. 3 in which like reference numerals refer to like features in FIG. 2, 2A and at a subsequent fabrication stage, a dielectric layer 48 may be formed over the photodetector 12 and waveguide core 14. The dielectric layer 48 may be comprised of a dielectric material, such as an oxide of silicon (e.g., silicon dioxide), having a refractive index that is less than the refractive index of the material constituting the waveguide core 14. Contacts 50 may be formed that are coupled to the conductor layer 42, contacts 52 may be formed that are coupled to the doped region 34, and contacts 51 may be formed that are coupled to the doped region 32. The contacts 50, 51, 52 may be comprised of a metal, such as tungsten.

The contacts 51, 52 may be used to supply a bias voltage to the photodetector 12 and to thereby collect charge carriers during operation of the photodetector 12. The contacts 50 may be used to bias the conductor layer 42 during operation of the photodetector 12. The conductor layer 42 is capacitively coupled to the doped region 24. A voltage applied to the conductor layer 42 creates a depletion region in the doped region 24 that affects (e.g., increases) the lateral electric-field in the undoped region 28.

The photodetector 12 may be characterized as a lateral avalanche photodetector with a separate absorption, charge, and multiplication (SACM) layer design. The semiconductor layer 40 represents an absorption layer of the photodetector 12, the doped region 24 represents a charge layer of the photodetector 12, and the intrinsic semiconductor material of the undoped region 28 of the pad 20 between the doped region 22 and the doped region 24 represents a multiplication layer of the photodetector 12. The charge layer and the multiplication layer are laterally arranged inside the pad 20.

In use, light propagating in the waveguide core 14 is coupled from tapered section of the waveguide core 14 to the semiconductor layer 40 of the photodetector 12. In an embodiment, the light received by the photodetector 12 may be laser light that is modulated as an optical signal. The semiconductor layer 40 of the photodetector 12 absorbs photons of the light and converts the absorbed photons into charge carriers by photoelectric conversion. The bias voltage applied to the doped regions 32, 34 causes the charge carriers to be collected and output to provide, as a function of time, a measurable photocurrent.

The conductor layer 42 of the photodetector 12 provides a terminal, in addition to the terminal provided by the doped region 32 and the terminal provided by the doped region 34, that can be biased with a control voltage during operation to manipulate the lateral electric field inside the undoped region 28 and to thereby dynamically tune the gain of the photodetector 12. Instituting the functionality of adaptive gain control in the photodetector 12 may be useful for applications, such as wavelength division multiplexing applications or any multi-channel receiver systems. Adaptive gain control may be used to dynamically optimize the signal-to-noise ratio of the photodetector 12, which may be useful for applications such as light detection and ranging sensing technologies or coherent multicolor-based receivers. The reliability of the photodetector 12 may be improved by lowering the operating voltage because of availability of the adaptive gain control.

The doped regions 36, 38, which are optional, may function to suppress dark current flowing along the interface at the top surface 21 between the semiconductor layer 40 and the pad 20. The doped regions 36, 38 may manipulate the electric field at the interface between the semiconductor layer 40 and the pad 20 to provide the dark current suppression. The doped regions 36, 38 lack connections to contacts and, for that reason, are electrically floating in the photodetector 12 during operation.

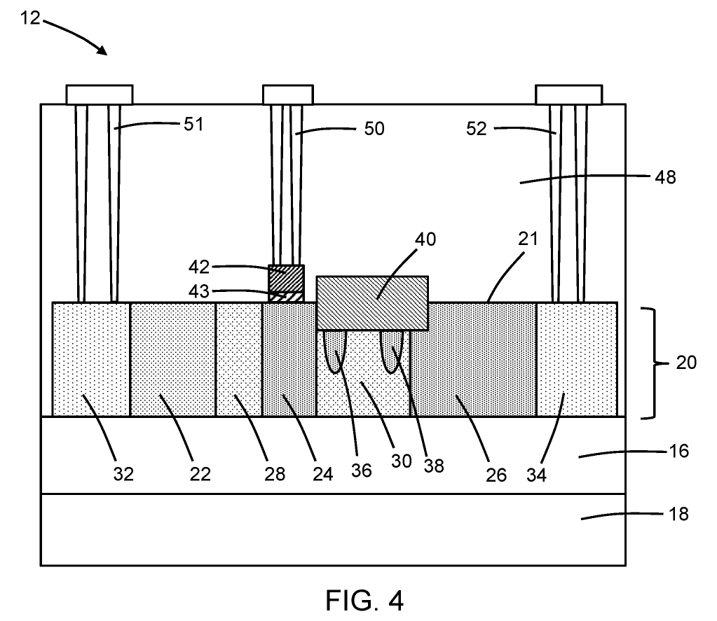

With reference to FIG. 4 and in accordance with alternative embodiments, the semiconductor layer 40 of the photodetector 12 be formed in a recess patterned in the pad 20 and extend into the undoped region 30. The semiconductor layer 40 may include an upper portion that is arranged above the top surface 21 of the pad 20 and a lower portion that is arranged below the top surface 21 of the pad 20. The conductor layer 42 and the insulator layer 43 providing the additional terminal of the photodetector 12 are arranged to overlie a portion of the doped region 24 adjacent to the recessed semiconductor layer 40.

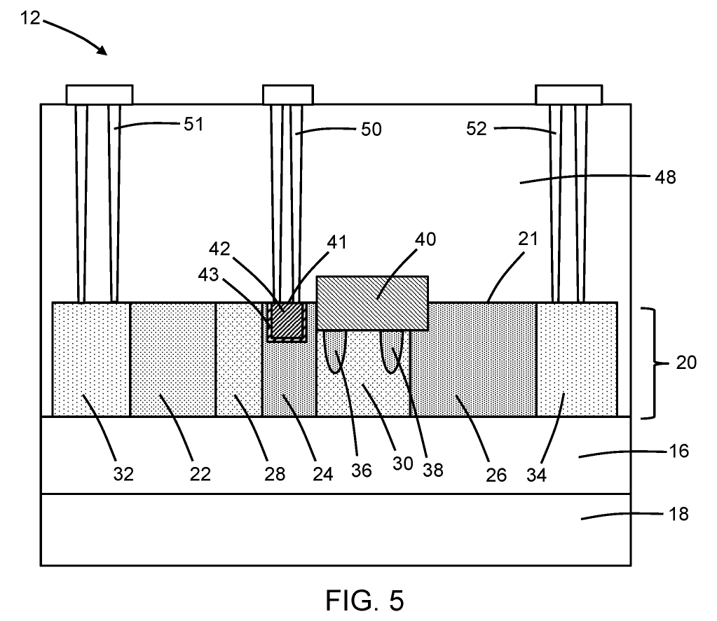

With reference to FIG. 5 and in accordance with alternative embodiments, a recess may be patterned by lithography and etching processes in the doped region 24 and the conductor layer 42 and the insulator layer 43 may be formed inside the recess. In an embodiment, an upper surface 41 of the conductor layer 42 may be coplanar with the top surface 21 of the pad 20. In an embodiment, an upper surface 41 of the conductor layer 42 may be substantially coplanar with the top surface 21 of the pad 20. The insulator layer 43 may wrap around multiple sides of the conductor layer 42 to electrically isolate the conductor layer 42 from the doped region 24. In an embodiment, the insulator layer 43 may be positioned fully between the conductor layer 42 and the doped region 24. The insulator layer 43 adjoins the doped region 22 at the bottom of the recess along a horizontal interface.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value or precise condition as specified. In embodiments, language of approximation may indicate a range of +/- 10% of the stated value(s) or the stated condition(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction in the frame of reference perpendicular to the horizontal plane, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or in “direct contact” with another feature if intervening features are absent. A feature may be “indirectly on” or in “indirect contact” with another feature if at least one intervening feature is present. A feature may “overlie” another feature if the feature is positioned in elevation over another feature. Different features may “overlap” if a feature extends over, and covers all or a part of, another feature. A feature may “underlie” another feature if the feature is positioned in elevation below another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure for a photonic chip, the structure comprising:
a photodetector including a pad comprised of a semiconductor material, a conductor layer, a first undoped region in the pad, a second undoped region in the pad, a first doped region in the pad, and a semiconductor layer on the first undoped region, the first doped region laterally arranged between the first undoped region and the second undoped region, and the conductor layer overlying the first doped region.

2. The structure of claim 1 wherein the pad has a side edge, and further comprising:
a waveguide core including a section adjoined to the side edge of the pad.

3. The structure of claim 1 wherein the photodetector further includes an insulator layer between the conductor layer and the first doped region.

4. The structure of claim 3 wherein the pad has a top surface, and the insulator layer is arranged fully between the conductor layer and the top surface.

5. The structure of claim 4 wherein the insulator layer adjoins the first doped region along a first interface, and the first interface is oriented in a horizontal direction relative to the top surface of the pad.

6. The structure of claim 4 wherein the first doped adjoins the first undoped region along a second interface, and the second interface is oriented in a vertical direction relative to the top surface of the pad.

7. The structure of claim 3 wherein the pad has a top surface and a recess extending from the top surface into the first doped region, the conductor layer is arranged inside the recess, and the insulator layer is arranged inside the recess fully between the conductor layer and the first doped region.

8. The structure of claim 7 wherein the conductor layer includes an upper surface is coplanar with the top surface of the pad.

9. The structure of claim 7 wherein the insulator layer adjoins the first doped region along a first interface at a bottom of the recess, and the first interface is oriented in a horizontal direction relative to the top surface of the pad.

10. The structure of claim 9 wherein the first doped region adjoins the first undoped region along a second interface, and the second interface is oriented in a vertical direction relative to the top surface of the pad.

11. The structure of claim 1 wherein the pad includes a second doped region in the first undoped region, the second doped region extends partially through the pad, and the semiconductor layer fully overlaps with the second doped region.

12. The structure of claim 1 wherein the photodetector includes a second doped region in the pad, the first doped region has a first conductivity type, the second doped region has a second conductivity type opposite to the first conductivity type, and the second undoped region is laterally positioned between the first doped region and the second doped region.

13. The structure of claim 12 wherein the first conductivity type is p-type, and the second conductivity type is n-type.

14. The structure of claim 12 wherein the photodetector includes a third doped region in the pad, the third doped region has the first conductivity type, and the first undoped region is laterally positioned between the first doped region and the third doped region.

15. The structure of claim 14 further comprising:
a semiconductor substrate; and
a first dielectric layer on the semiconductor substrate,
wherein the pad is positioned on the first dielectric layer.

16. The structure of claim 15 further comprising:
a second dielectric layer on the first dielectric layer; and
a first contact in the second dielectric layer, the first contact coupled to the conductor layer.

17. The structure of claim 16 further comprising:
a second contact in the second dielectric layer, the second contact coupled to the second doped region; and
a third contact in the second dielectric layer, the third contact coupled to the third doped region.

18. The structure of claim 1 further comprising:
a semiconductor substrate; and
a first dielectric layer on the semiconductor substrate,
wherein the pad is positioned on the first dielectric layer.

19. The structure of claim 18 further comprising:
a second dielectric layer on the first dielectric layer; and
a contact in the second dielectric layer, the contact coupled to the conductor layer.

20. A method of forming a structure for a photonic chip, the method comprising:
forming a photodetector including a pad comprised of a semiconductor material, a conductor layer, a first undoped region in the pad, a second undoped region in the pad, a first doped region in the pad, and a semiconductor layer on the first undoped region, wherein the first doped region is laterally arranged between the first undoped region and the second undoped region, and the conductor layer overlies the first doped region.
